(19) United States
(12) Patent Application Publication
(10) Pub. No.: US 2013/0302954 A1
(43) Pub. Date: Nov. 14, 2013

(54) METHODS OF FORMING FINS FOR A FINFET DEVICE WITHOUT PERFORMING A CMP PROCESS

(71) Applicant: Robert C. Lutz, Dresden (DE)

(72) Inventor: Robert C. Lutz, Dresden (DE)

(73) Assignee: GLOBALFOUNDRIES INC., Grand Cayman (KY)

(21) Appl. No.: 13/468,183

(22) Filed: May 10, 2012

(51) Int. Cl. H01L 21/336

(52) U.S. Cl. 438/197; 257/E21.409

(57) ABSTRACT

One illustrative method disclosed herein includes forming a layer of insulating material above a surface of a semiconducting substrate, performing a first etching process on the layer of insulating material to define a plurality of trenches in the layer of insulating material, wherein each of the trenches exposes a portion of the surface of the substrate, performing an epitaxial growth process to form a fin comprised of a semiconductor material in each of the trenches, and, after forming the fins, performing a second etching process on the layer of insulating material to thereby reduce a thickness of the layer of insulating material and thereby define a local isolation region positioned between the plurality of fins.

### BACKGROUND OF THE INVENTION

1. Field of the Invention

Generally, the present disclosure relates to the manufacture of sophisticated semiconductor devices, and, more specifically, to various methods of forming fins for a FinFET semiconductor device without performing a chemical mechanical polishing process.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Metal oxide field effect transistors (MOSFETs or FETs) represent one important type of circuit element that substantially determines performance of such integrated circuit devices. A FET is a device that typically includes a source region, a drain region, a channel region that is positioned between the source region and the drain region, and a gate electrode positioned above the channel region. Current flow through the FET is controlled by controlling the voltage applied to the gate electrode. If a voltage that is less than the threshold voltage of the device is applied to the gate electrode, then there is no current flow through the device (ignoring undesirable leakage currents, which are relatively small). However, when a voltage that is equal to or greater than the threshold voltage of the device is applied to the gate electrode, the channel region becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the channel from being adversely affected by the electrical potential of the drain. This is sometimes referred to as a so-called short channel effect, wherein the characteristic of the FET as an active switch is degraded.

In contrast to a planar FET, which has a planar structure, there are so-called 3D devices, such as an illustrative FinFET device, which is a 3-dimensional structure. More specifically, in a FinFET device, a generally vertically positioned fin-shaped active area is formed and a gate electrode encloses both sides and an upper surface of the fin-shaped active area to form a tri-gate structure so as to use a channel having a 3-dimensional structure instead of a planar structure. In some cases, an insulating cap layer, e.g., silicon nitride, is positioned at the top of the fin and the FinFET device only has a dual-gate structure. Unlike a planar FET, in a FinFET device, a conductive channel is formed perpendicular to a surface of the semiconducting substrate so as to reduce the depletion width under the channel and thereby reduce so-called short channel effects. Also, in a FinFET device, the junction capacitance at the drain region of the device is greatly reduced, which tends to reduce at least some short channel effects.

FIGS. 1A-1H depict one illustrative prior art process flow that may be formed to form a FinFET device 100 in and above a semiconducting substrate 10. At the point of fabrication depicted in FIG. 1A, a patterned mask layer 16, such as a patterned hard mask layer (e.g., silicon nitride), has been formed above the substrate 10 using known photolithography and etching techniques. With continuing reference to FIG. 1A, an etching process, such as a dry or wet etching process, is performed on the substrate 10 through the patterned mask layer 16 to form a plurality of trenches 14 in the substrate 10. This etching process results in the definition of a plurality of fins 20. The overall size, shape, depth, width and configuration of the trenches 14 and fins 20 may vary depending on the particular application. In the illustrative example depicted in FIGS. 1A-1H, the trenches 14 and fins 20 are all of a uniform size and shape. However, such uniformity in the size and shape of the trenches 14 and the fins 20 is not required in all applications. In the example depicted herein, the trenches 14 are formed by performing an anisotropic etching process that results in the trenches 14 having a schematically depicted, generally rectangular configuration. In an actual real-world device, the sidewalls of the trenches 14 may be somewhat inwardly tapered, although that configuration is not depicted in the drawings.

In FIG. 1B, a layer of insulating material 24 has been blanket-deposited such that it overfills the trenches 14. The layer of insulating material 24 may be made of a variety of materials, such as silicon dioxide, etc. The layer of insulating material 24 may be formed by performing any of a variety of known processes, such as a chemical vapor deposition (CVD) process, etc.

FIG. 1C depicts the device 100 after a chemical mechanical polishing (CMP) process has been performed on the as deposited surface of the layer insulating material 24 using the patterned hard mask layer 16 as a polish-stop layer. This CMP process is intended to result in the upper surface 24U of the layer of insulating material 24 being substantially planar with the upper surface 16U of the patterned mask layer 16.

As shown in FIG. 1D, an etching process is performed to recess the layer of insulating material 24 to define local isolation regions 24A for the device 100. In one illustrative embodiment, after the etching process is completed, the local isolation regions 24A may have a thickness of about 20-200 nm. As depicted, the recessed upper surface 24R of the local isolation regions 24A is below the upper surface 20U of the fins 20

Next, as shown in FIGS. 1E (cross-sectional view) and 1F (plan view of the device shown in FIG. 1E), a gate structure 26 comprised of a gate insulation layer 26A and a gate electrode 26B is formed on the device 100. The gate insulation layer 26A may be made of a variety of materials such as, for example, silicon dioxide, etc., and it may be formed by a variety of processes, e.g., an oxidation process, a CVD process, etc. In the illustrative example depicted in FIG. 1E, the gate insulation layer 26A is comprised of a thermally grown layer of silicon dioxide. The gate electrode 26B may also be made of a variety of materials, e.g., polysilicon, amorphous silicon, silicon/germanium (SiGe), etc., and it may be formed by a CVD process. After the materials for the gate structure 26 are formed, one or more etching processes may be performed on the various layers of material to define the gate structure 26. In some applications, the gate structure 26 may be sacrificial in nature as the final gate structure for the device may be formed using well-known replacement gate techniques.

Next, as shown in FIGS. 1G (a cross-sectional view) and 1H (a plan view of the device shown in FIG. 1G), one or more sidewall spacers 28 are formed proximate the gate structure 26. The sidewall spacers 28 may be made of a variety of materials, such as, for example, silicon nitride. The sidewall spacers 28 may be formed by conformably depositing a layer of spacer material and thereafter performing an anisotropic etching process. After the sidewall spacers 28 are formed, one or more ion implantation processes may be performed through a patterned mask layer (not shown) to introduce dopant materials (N-type or P-type dopants depending upon the device under construction) into the area of the fins 20 not covered by the gate structure 26 and the spacers 28 and thereby form source/drain regions for the device 100. After the dopant materials are introduced into the exposed portions of the fins 20, an anneal process may be performed to activate the implanted dopant material and to repair any damage to the fins 20 due to the implantation process. If desired, metal silicide regions (not shown) may also be formed at this time on the exposed portions of the fins 20. Additional operations are typically performed to complete the fabrication of the device 100, e.g., the formation of conductive contacts to the source/drain regions of the device 100, the formation of various metallization layers that constitute the wiring structure for an integrated circuit product, etc.

While the aforementioned process has been used to form FinFET devices, it is not without drawbacks. More specifically, CMP processes that are performed to planarize the upper surface 24U of the layer of insulating material 24 with the upper surface 16U of the patterned mask layer 16 are very difficult to control. For example, such CMP processes may lead to unacceptable dishing of the isolation material and the generation of scratches on the fins 20, etc. CMP processes often exhibit significant cross-wafer variations, e.g., so-called “roll-off,” that tends to result in very poor yields for devices located proximate the edge of the substrate.

The present disclosure is directed to various methods that may reduce or eliminate one or more of the problems noted above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming fins for a FinFET semiconductor device without performing a CMP process. One illustrative method disclosed herein includes forming a layer of insulating material above a surface of a semiconducting substrate, performing a first etching process on the layer of insulating material to define a plurality of trenches in the layer of insulating material, wherein each of the trenches exposes a portion of the surface of the substrate, performing an epitaxial growth process to form a fin comprised of a semiconductor material in each of the trenches and, after forming the fins, performing a second etching process on the layer of insulating material to thereby reduce a thickness of the layer of insulating material and thereby define a local isolation region positioned between the plurality of fins.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1H depict one illustrative prior art method of forming FinFET semiconductor devices; and

FIG. 2A-2H depict one illustrative method disclosed herein for fins for a FinFET semiconductor device without performing a CMP process.

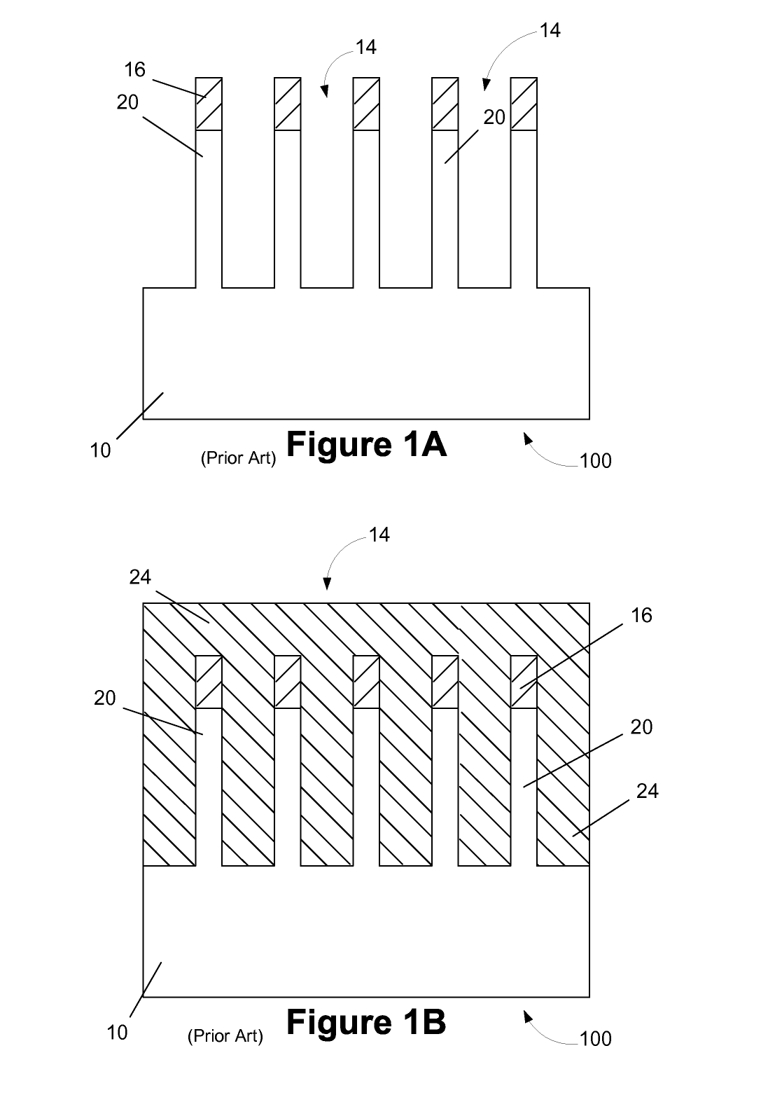

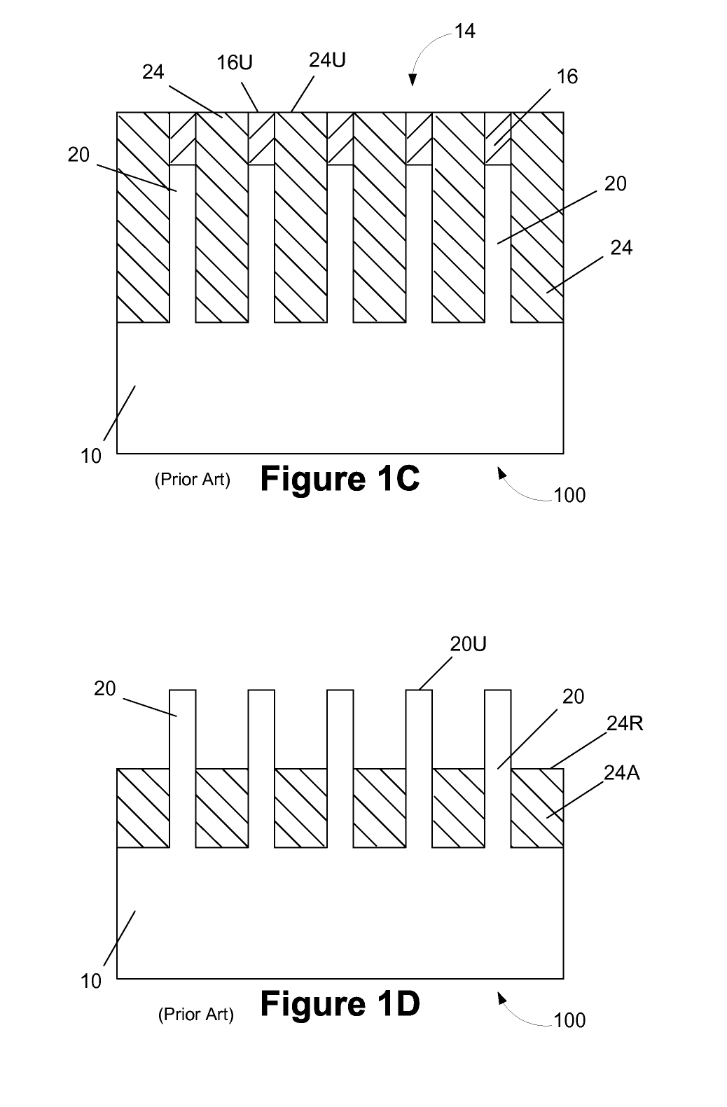

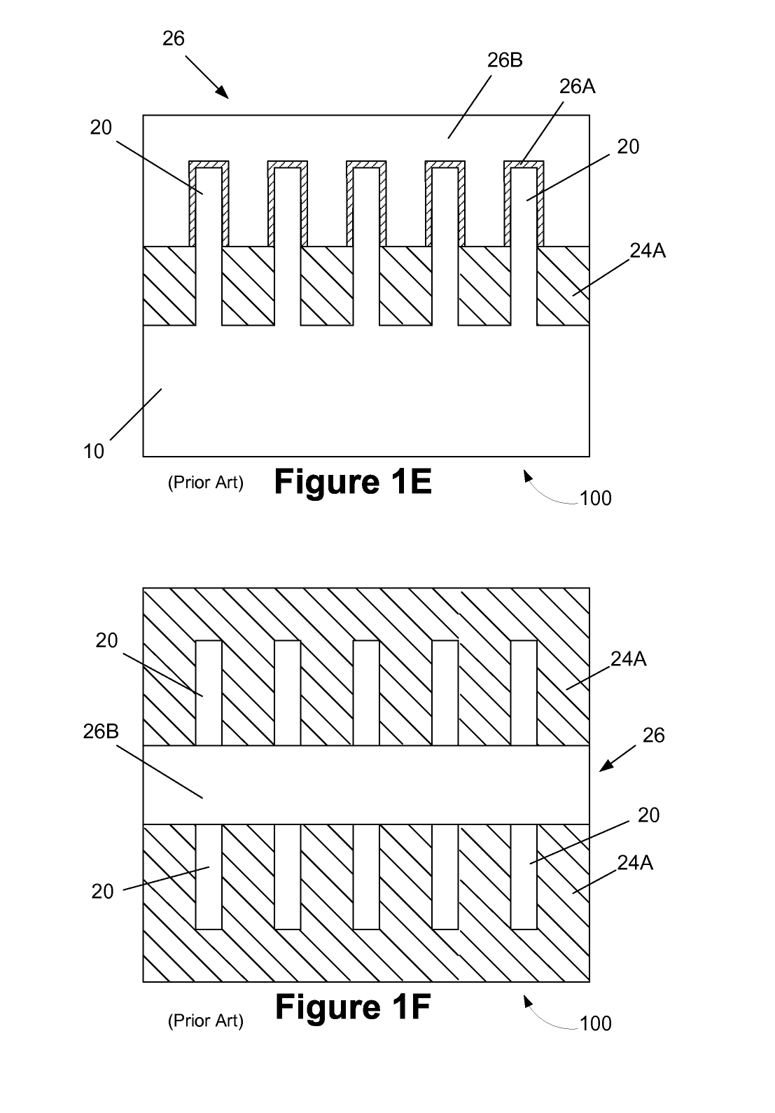

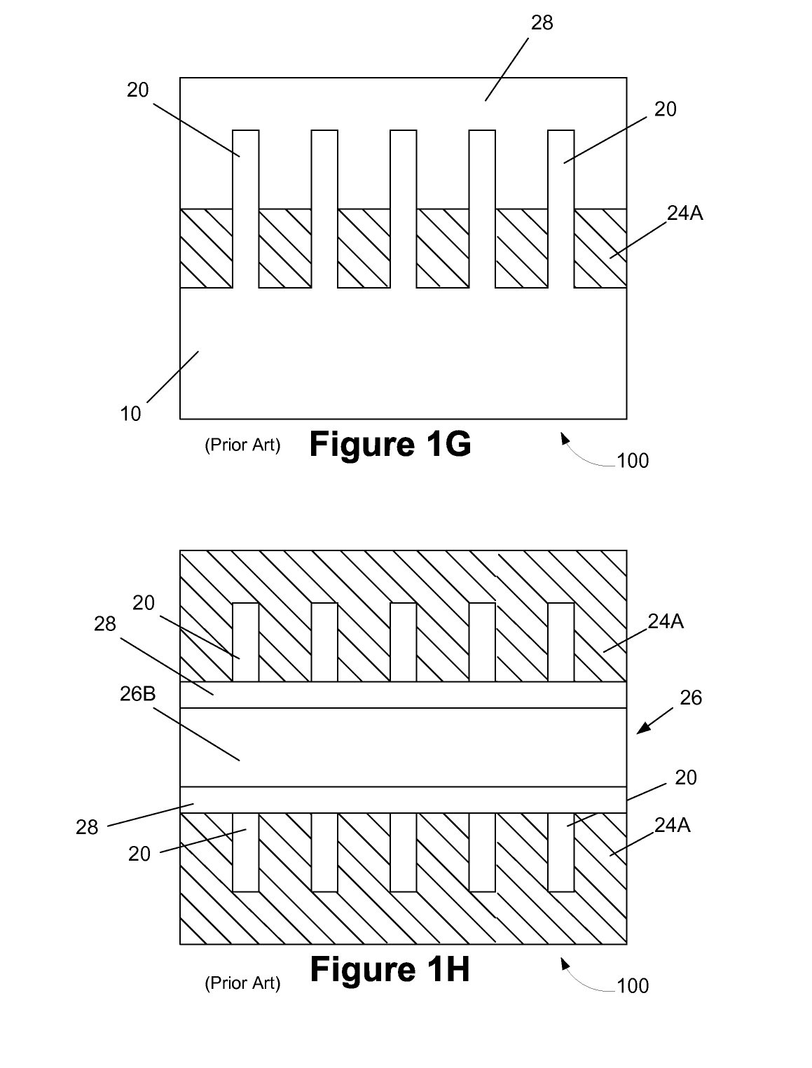

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming fins for a FinFET semiconductor device without performing a CMP process. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

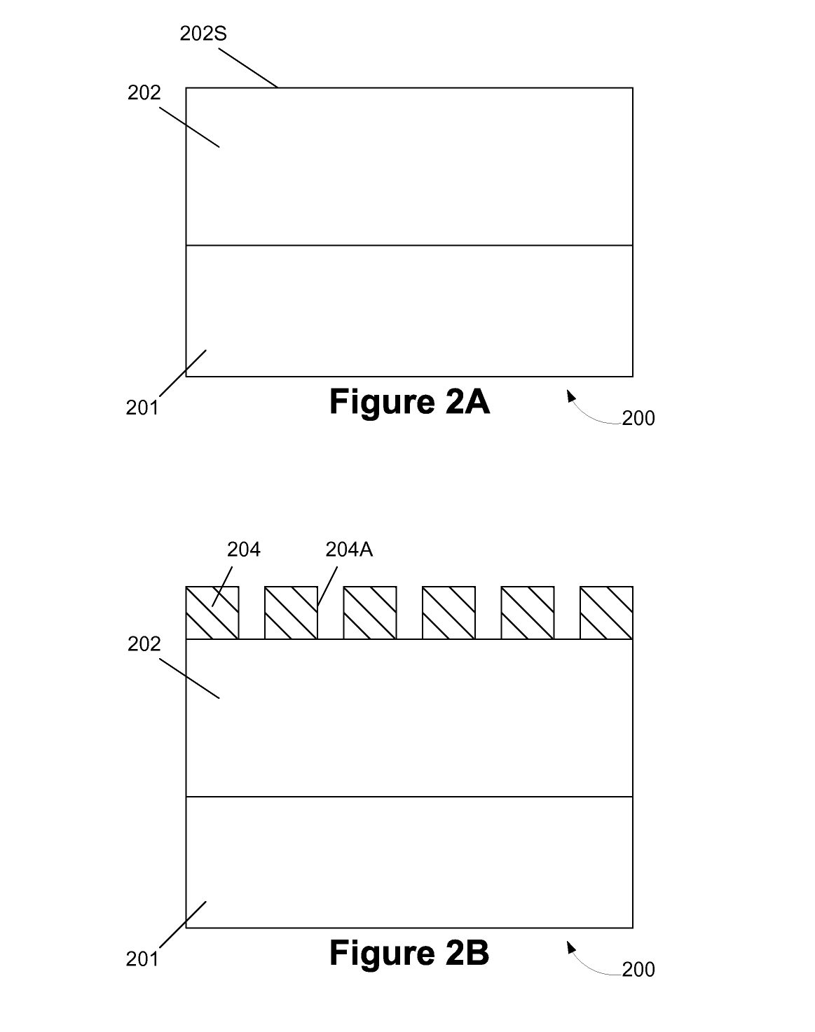

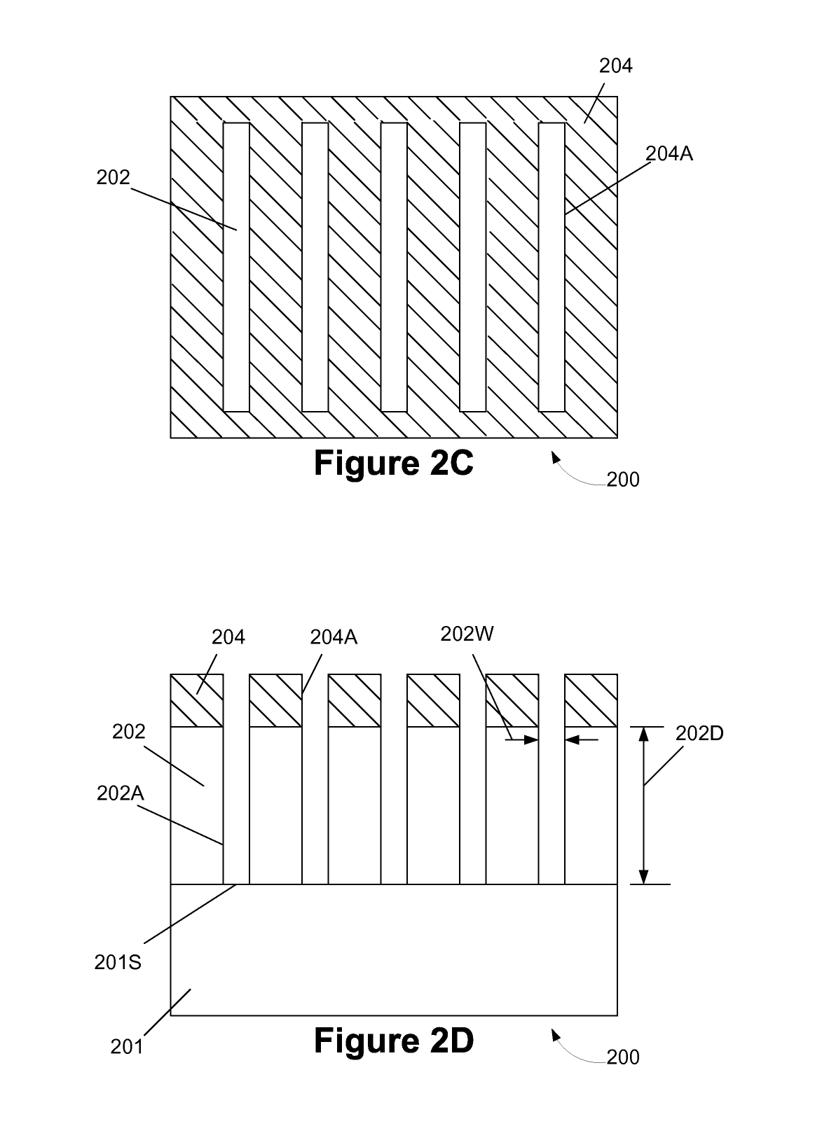

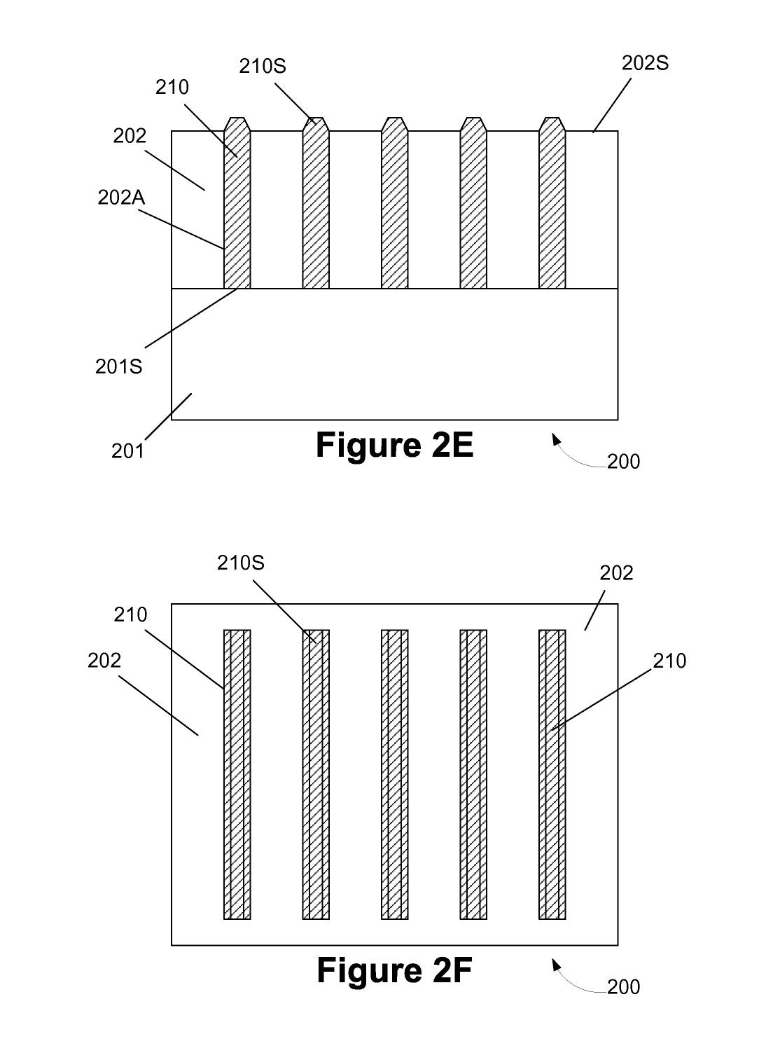

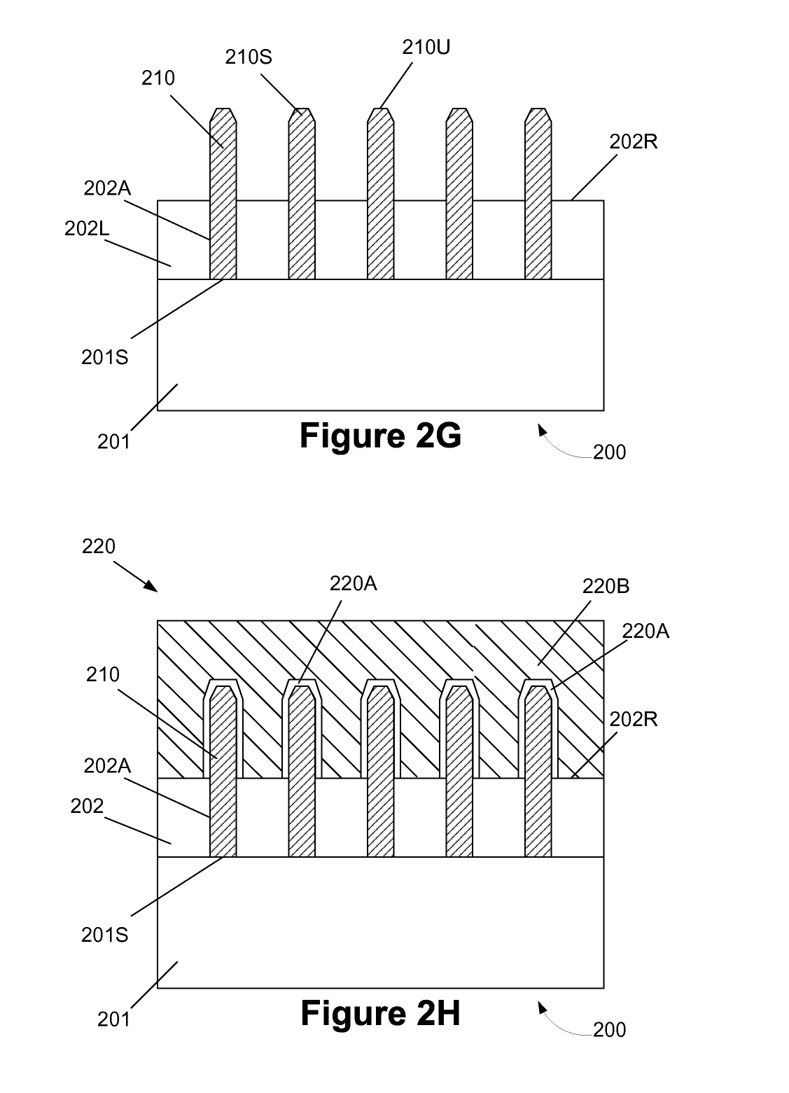

FIG. 2A is a simplified view of an illustrative FinFET semiconductor device 200 at an early stage of manufacturing that is formed above a semiconducting substrate 201. The substrate 201 may have a variety of configurations, such as the depicted bulk silicon configuration. The substrate 201 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 201 may also be made of materials other than silicon.

At the point of fabrication depicted in FIG. 2A, a layer of insulating material 202 is formed above the substrate 201. The layer of insulating material 202 may be made of a variety of materials, such as silicon dioxide, silicon oxycarbide, silicon oxynitride, etc. The layer of insulating material 202 may be formed by performing any of a variety of known processes, such as a thermal oxidation process, a chemical vapor deposition (CVD) process, an atomic layer deposition (ALD) process, or plasma-enhanced versions of such processes. The thickness of the layer of insulating material 202 may vary depending upon the particular application, e.g., it may have a thickness within the range of about 50-400 nm. The layer of insulating material has an as-formed or as-deposited upper surface 202S.

Next, as shown in FIG. 2B (cross-sectional view) and FIG. 2C (plan view), a patterned etch mask layer 204, such as a patterned hard mask layer, or a patterned layer of photoresist material, has been formed above the layer of insulating material 202 using known photolithography and/or etching techniques. The patterned etch mask layer 204 has a plurality of line-type features 204A defined therein that exposes portions of the underlying layer of insulating material 202 for further processing. The patterned etch mask layer 204 is intended to be representative in nature as it could be comprised of a variety of materials, such as, for example, a photoresist material, silicon nitride, silicon oxynitride, silicon dioxide, etc. Moreover, the patterned etch mask layer 204 could be comprised of multiple layers of material. Thus, the particular form and composition of the patterned etch mask layer 204 and the manner in which it is made should not be considered a limitation of the presently disclosed inventions.

Next, as shown in FIG. 2D, an etching process, such as a dry or wet etching process, is performed on the layer of insulating material 202 through the patterned etch mask layer 204 to form a plurality of trenches 202A in the layer of insulating material 202. The trenches 202A expose portions of the upper surface 201S of the substrate 201. The overall size, shape and configuration of the trenches 202A may vary depending on the particular application. The depth 202D and width 202W of the trenches 202A may vary depending upon the particular application. In one illustrative embodiment, based on current day technology, the depth 202D of the trenches 202A may range from approximately 50-400 nm and the width 202W of the trenches 202A at the top of the trenches may range from about 10-100 nm. In the illustrative example depicted in FIG. 2D, the trenches 202A are all of a uniform size and shape. However, such uniformity in the size and shape of the trenches 202A is not required to practice at least some aspects of the inventions disclosed herein. In the example depicted herein, the trenches 202A are formed by performing a dry anisotropic etching process that results in the trenches 202A having a schematically depicted, generally rectangular configuration. In an actual real-world device, the sidewalls of the trenches 202A may be somewhat inwardly tapered, although that configuration is not depicted in the drawings. Thus, the size and configuration of the trenches 202A, and the manner in which they are made, should not be considered a limitation of the presently disclosed inventions. For ease of disclosure, only the substantially rectangular trenches 202A will be depicted in subsequent drawings.

Next, as shown in FIG. 2E (cross-sectional view) and FIG. 2F (plan view), an epitaxial deposition process is performed to grow a semiconductor material in the trenches 202A using the exposed portions of the substrate 201 as the seed material. This process results in the definition of a plurality of fins 210 in the trenches 202A, wherein the fins 210 are comprised of the epitaxially-formed semiconductor material. Note that the upper portion 210S of the fins 210 exhibits a faceted surface due to the crystalline nature of the epitaxial growth process that is performed to form the fins 210.

Then, as shown in FIG. 2G, an etching process is performed on the as-formed or as-deposited upper surface 202S (see FIG. 2E) of the layer of insulating material 202 to reduce the thickness of the layer of insulating material 202 and thereby define local isolation regions 202L for the device 200. In one illustrative embodiment, after the etching process is completed, the local isolation regions 202L may have a thickness of about 20-200 nm. As depicted, the recessed upper surface 202R of the local isolation regions 202L is below the upper surface 210U of the fins 210. Typically, the recessed upper surface 202R of the local isolation regions 202L defines the final fin height for the fins 210. Note that, in this process flow, the fins 210 and the final fin height has been defined without performing a CMP process, as was performed in the prior art method described in the background section of this application. Accordingly, the problems that are frequently encountered when using such CMP processes are avoided using the novel process flow described herein.

At this point in the process flow, traditional operations may be performed to complete the fabrication of the device 200. For example, as shown in FIG. 2H a gate structure 220 comprised of a gate insulation layer 220A and a gate electrode 220B is formed on the device 200. The gate insulation layer 220A may be made of a variety of materials such as, for example, silicon dioxide, etc., and it may be formed by a variety of processes, e.g., an oxidation process, a CVD process, etc. In the illustrative example depicted in FIG. 2H, the gate insulation layer 220A is comprised of a thermally grown layer of silicon dioxide. The gate electrode 220B may also be made of a variety of materials, e.g., polysilicon, amorphous silicon, SiGe, etc., and it may be formed by a CVD process. After the materials for the gate structure 220 are formed, one or more etching processes may be performed on the layer of materials to define the gate structure 220. Although not depicted in the drawings, after the gate structure 220 is formed, one or more sidewall spacers (not shown) may be formed proximate the gate structure 220 by conformably depositing a layer of spacer material and thereafter performing an anisotropic etching process. Then, one or more ion implantation processes may be performed through a patterned mask layer (not shown) to introduce dopant materials (N-type or P-type dopants depending upon the type of device under construction) into the area of the fins 210 not covered by the gate structure 220 (and the sidewall spacers) to thereby form source/drain regions for the device 200. After the dopant materials are introduced into the exposed portions of the fins 210, an anneal process may be performed to activate the implanted dopant material and to repair any damage to the fins 210 due to the implantation process. If desired, metal silicide regions may also be formed at this time on the exposed portions of the fins 210. In some applications, the gate insulation layer 220A depicted in FIG. 2H may be sacrificial in nature.

As will be appreciated by those skilled in the art after reading the present application, the methods disclosed herein may be employed to manufacture devices using either so-called “gate-first” or “replacement gate” (RMG) techniques. In the case where replacement gate techniques will be employed to manufacture the final device 200, the gate structure 220, i.e., the gate insulation layer 220A and the gate electrode 220B, may be sacrificial in nature and they may be replaced with a replacement gate structure (not shown). In one example, such a replacement gate structure may be comprised of one or more so-called high-k insulating materials (k value greater than 10) and one or more metal layers. In some cases, the replacement gate structure may also be comprised of a layer of polysilicon formed above any such metal layers.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a FinFET device, comprising:
forming a layer of insulating material above a surface of a semiconducting substrate;
performing a first etching process on said layer of insulating material to define a plurality of trenches in said layer of insulating material, each of said plurality of trenches exposing a portion of said surface of said substrate;
performing an epitaxial growth process to form a fin in each of said trenches, wherein said fins are comprised of a semiconductor material; and
after forming said fins, performing a second etching process on said layer of insulating material to thereby reduce a thickness of said layer of insulating material and thereby define a local isolation region positioned between said plurality of fins.

2. The method of claim 1, further comprising forming a gate structure above said plurality of fins and said local isolation region.

3. The method of claim 2, wherein said gate structure is a final gate structure for a semiconductor device.

4. The method of claim 2, wherein said gate structure is a sacrificial gate structure that will be removed and replaced with a replacement gate structure for a semiconductor device.

5. The method of claim 2, wherein said layer of insulating material is comprised of silicon dioxide, silicon oxycarbide or silicon oxynitride.

6. The method of claim 1, wherein said substrate and said plurality of fins are comprised of silicon.

7. The method of claim 1, wherein each of said plurality of fins has a faceted upper portion.

8. The method of claim 1, wherein, after said second etching process is performed on said layer of insulating material, an upper surface of said local isolation region defines a fin height of said plurality of fins.

9. The method of claim 1, wherein performing said first etching process comprises performing one of a wet or a dry etching process.

10. The method of claim 1, wherein performing said second etching process comprises performing one of a wet or a dry etching process.

11. The method of claim 1, wherein forming said layer of insulating material above said surface of said semiconducting substrate comprises depositing said layer of insulating material above said surface of said semiconducting substrate, wherein said layer of insulating material has an as-deposited upper surface.

12. The method of claim 11, wherein performing said second etching process on said layer of insulating material to thereby reduce a thickness of said layer of insulating material and thereby define a local isolation region comprises performing said second etching process on said as-deposited surface of said layer of insulating material to thereby reduce said thickness of said layer of insulating material and thereby define said local isolation region.

13. A method of forming a FinFET device, comprising:
depositing a layer of insulating material on a surface of a semiconducting substrate comprised of silicon, said layer of insulating material having an as-deposited upper surface;
performing a first etching process on said layer of insulating material to define a plurality of trenches in said layer of insulating material, each of said plurality of trenches exposing a portion of said surface of said substrate;
performing an epitaxial growth process to form a fin in each of said trenches, wherein said fins are comprised of silicon; and
after forming said fins, performing a second etching process on said as-deposited upper surface of said layer of insulating material to thereby reduce a thickness of said layer of insulating material and thereby define a local isolation region positioned between said plurality of fins.

14. The method of claim 13, further comprising forming a gate structure above said plurality of fins and said local isolation region.

15. The method of claim 13, wherein said layer of insulating material is comprised of silicon dioxide, silicon oxycarbide or silicon oxynitride.

16. The method of claim 13, wherein each of said plurality of fins has a faceted upper portion.

17. The method of claim 13, wherein, after said second etching process is performed on said as-deposited surface of said layer of insulating material, an upper surface of said local isolation region defines a fin height of said plurality of fins.

18. The method of claim 13, wherein performing said first etching process comprises performing one of a wet or a dry etching process.

19. The method of claim 13, wherein performing said second etching process comprises performing one of a wet or a dry etching process.
